(19) United States
(12) Patent Application Publication
(10) Pub. No.: US 2015/0137299 A1
(43) Pub. Date: May 21, 2015

(54) SOLID STATE IMAGING DEVICE AND MANUFACTURING METHOD FOR SOLID STATE IMAGING DEVICE

(71) Applicant: Kabushiki Kaisha Toshiba, Minato-ku (JP)

(72) Inventor: Tetsuya YAMAGUCHI, Oita (JP)

(73) Assignee: Kabushiki Kaisha Toshiba, Minato-ku (JP)

(21) Appl. No.: 14/474,608

(22) Filed: Sep. 2, 2014

(30) Foreign Application Priority Data
Nov. 19, 2013 (JP) 2013-239328

(51) Int. Cl. H01L 27/146

(52) U.S. Cl. CPC H01L 27/14623; H01L 27/1463; H01L 27/14643; H01L 27/14683
USPC 257/435; 438/73

(57) ABSTRACT

There is provided a solid state imaging device according to the embodiment. The solid state imaging device includes an imaging area and an element isolation unit having a light shielding effect. In the imaging area, a plurality of photoelectric conversion elements is two-dimensionally arranged in a matrix in a semiconductor layer. The element isolation unit is embedded so as to surround a light-receiving region of each photoelectric conversion element. A center position of an opening region surrounding the light-receiving region is positioned on the center side of the imaging area than a corresponding center position of the light-receiving region.

### CROSS-REFERENCE TO RELATED APPLICATIONS

This application is based upon and claims the benefit of priority from Japanese Patent Application No. 2013-239328, filed on Nov. 19, 2013; the entire contents of which are incorporated herein by reference.

### FIELD

The present embodiment generally relates to a solid state imaging device and a manufacturing method for the solid state imaging device.

### BACKGROUND

Traditionally, an electronic device such as a digital camera and a mobile terminal with a camera function includes a camera module having a solid state imaging device. The solid state imaging device includes an imaging area where a plurality of photoelectric conversion elements is two-dimensionally arranged in a matrix in a semiconductor layer and images a subject image formed by an imaging optical system. Each photoelectric conversion element corresponds to each pixel, photoelectrically converts incident light into a charge of an amount according to the amount of the received light, and then accumulates the charge as a signal charge indicating luminance of each pixel.

Also, in the solid state imaging device, for example, light shielding films may be laminated and provided on a semiconductor layer around a light-receiving region of each photoelectric conversion element. The light shielding film is provided, for example, to define the light-receiving region of each photoelectric conversion element.

In the solid state imaging device, light which enters a central part of the imaging area via the imaging optical system vertically enters relative to an opening of the light shielding film. On the other hand, light which enters a peripheral edge part of the imaging area via the imaging optical system obliquely enters relative to the opening of the light shielding film.

Therefore, in the peripheral edge part of the imaging area, a part of the light is blocked by the light shielding film and does not reach the light-receiving region of the photoelectric conversion element. As a result, in the solid state imaging device, an amount of the received light of the photoelectric conversion element provided in the peripheral edge part of the imaging area is reduced as compared with an amount of the received light of the photoelectric conversion element provided in the central part of the imaging area. Therefore, decrease in the light-reception sensitivity (sensitivity shading) occurs.

### BRIEF DESCRIPTION OF THE DRAWINGS

FIG. 1 is a block diagram of an outline configuration of a digital camera according to the embodiment;

FIG. 2 is a block diagram of an outline configuration of a solid state imaging device according to the embodiment;

FIG. 3A is an explanatory diagram of a schematic configuration of a central part of a pixel array according to the embodiment;

FIG. 3B is an explanatory diagram of a schematic configuration of a peripheral edge part of the pixel array according to the embodiment;

FIG. 4 is an explanatory diagram of positional relationship between an opening region of an element isolation unit and a light-receiving region of a photoelectric conversion element of the pixel array according to the embodiment;

FIG. 5 is an explanatory diagram of a part of positional relationship between the opening region of the element isolation unit and the light-receiving region of the photoelectric conversion element according to the embodiment;

FIGS. 6A to 6C are cross-sectional schematic diagrams of manufacturing process for a solid state imaging device according to the embodiment;

FIGS. 7A and 7B are cross-sectional schematic diagrams of the manufacturing process for the solid state imaging device according to the embodiment;

FIGS. 8A and 8B are cross-sectional schematic diagrams of the manufacturing process for the solid state imaging device according to the embodiment;

FIGS. 9A and 9B are cross-sectional schematic diagrams of the manufacturing process for the solid state imaging device according to the embodiment; and

FIG. 10 is a cross-sectional explanatory diagram of a part of an image sensor according to another embodiment.

### DETAILED DESCRIPTION

There is provided a solid state imaging device according to the present embodiment. The solid state imaging device includes an imaging area and an element isolation unit having a light shielding effect. In the imaging area, a plurality of photoelectric conversion elements is two-dimensionally arranged in a matrix in a semiconductor layer. The element isolation unit is embedded so as to surround a light-receiving region of each photoelectric conversion element. A center position of an opening region surrounding the light-receiving region is positioned on the center side of the imaging area than a corresponding center position of the light-receiving region.

A solid state imaging device and a manufacturing method for the solid state imaging device according to the embodiment will be described in detail below with reference to the drawings. The present invention is not limited to the embodiment.

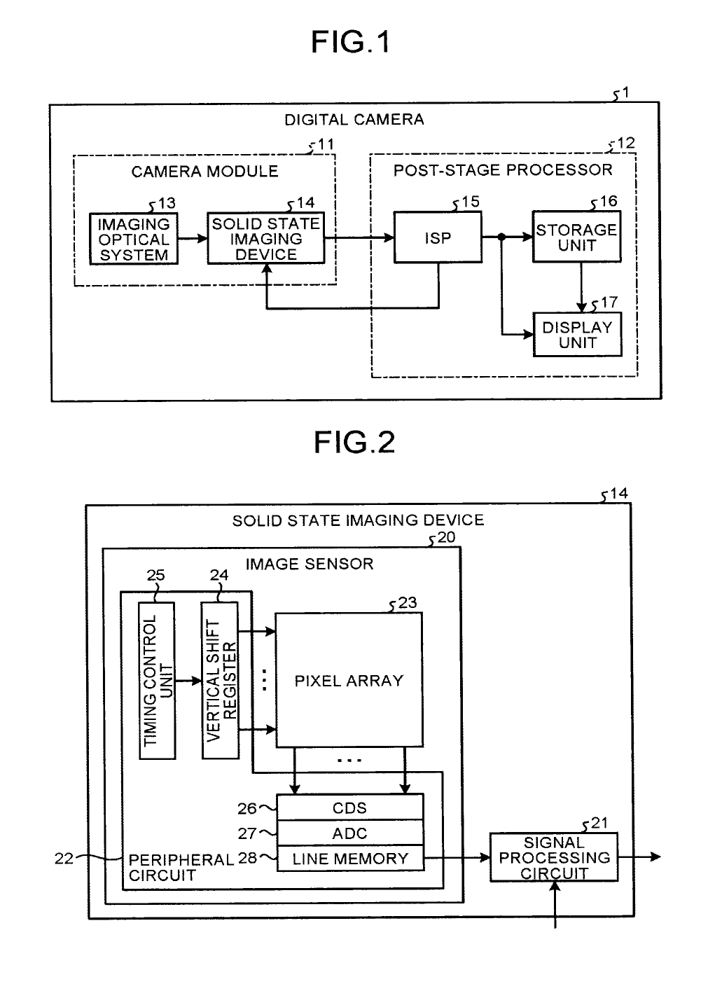

FIG. 1 is a block diagram of an outline configuration of a digital camera 1 having a solid state imaging device 14 according to the embodiment. The digital camera 1 includes a camera module 11 and a post-stage processor 12 as illustrated in FIG. 1.

The camera module 11 includes an imaging optical system 13 and the solid state imaging device 14. The imaging optical system 13 takes in light and forms an object image. The solid state imaging device 14 images the object image formed by the imaging optical system 13 and outputs an image signal obtained by imaging to the post-stage processor 12. The camera module 11 is applied to an electronic device, for example, a mobile terminal with a camera, other than the digital camera 1.

The post-stage processor 12 includes an image signal processor (ISP) 15, a storage unit 16, and a display unit 17. The ISP 15 performs signal processing to the image signal input from the solid state imaging device 14. The ISP 15 performs quality improving processing, for example, noise removing processing, defective pixel correcting processing, resolution converting processing, and the like.

The ISP 15 outputs the image signal after the signal processing to the storage unit 16, the display unit 17, and a signal processing circuit 21 to be described below included in the solid state imaging device 14 in the camera module 11 (refer to FIG. 2). The image signal fed back from the ISP 15 to the camera module 11 is used to adjust and control the solid state imaging device 14.

The storage unit 16 stores the image signal input from the ISP 15 as an image. Also, the storage unit 16 outputs the image signal of the stored image to the display unit 17 according to operation by a user and the like. The display unit 17 displays the image according to the image signal input from the ISP 15 or the storage unit 16. For example, the display unit 17 is a liquid crystal display.

Next, the solid state imaging device 14 included in the camera module 11 will be described with reference to FIG. 2. FIG. 2 is a block diagram of an outline configuration of the solid state imaging device 14 according to the embodiment. The solid state imaging device 14 includes an image sensor 20 and a signal processing circuit 21 as illustrated in FIG. 2.

Here, a case will be described where the image sensor 20 is a so-called rear surface irradiation type complementary metal oxide semiconductor (CMOS) image sensor in which a wiring layer is formed on an opposite surface to a surface, where the incident light enters, of the photoelectric conversion element for performing photoelectric conversion to the incident light.

The image sensor 20 according to the present embodiment is not limited to the rear surface irradiation type CMOS image sensor and may be an arbitrary image sensor such as a surface irradiation type CMOS image sensor and a charge coupled device (CCD) image sensor.

The image sensor 20 includes a peripheral circuit 22 and a pixel array 23. Also, the peripheral circuit 22 includes a vertical shift register 24, a timing control unit 25, a correlated double sampling (CDS) 26, an analog digital converter (ADC) 27, and a line memory 28.

The pixel array 23 is provided in a region where the light from the imaging optical system 13 of the image sensor 20 enters. In the pixel array 23, a plurality of photoelectric conversion elements corresponding to respective pixels of an imaged image is arranged in a shape of a two-dimensional array (matrix) in a horizontal direction (row direction) and a vertical direction (column direction). The pixel array 23 is the imaging area in the solid state imaging device 14. In the pixel array 23, the respective photoelectric conversion elements corresponding to the respective pixels generate and accumulate the signal charge (for example, electron) according to the amount of the incident light.

The timing control unit 25 is a processor for outputting a pulse signal which is a reference of operation timing relative to the vertical shift register 24. The vertical shift register 24 is a processor for outputting a selection signal to the pixel array 23. The selection signal is used to sequentially select photoelectric conversion elements row by row for reading the signal charge from among the plurality of photoelectric conversion elements which is two-dimensionally arranged in the shape of the array (matrix).

The pixel array 23 outputs the signal charge, which is accumulated in each photoelectric conversion element selected row by row by the selection signal input from the vertical shift register 24, from the photoelectric conversion element to the CDS 26 as a pixel signal indicating the luminance of each pixel.

The CDS 26 is a processor for removing a noise from the pixel signal input from the pixel array 23 by the correlated double sampling and outputting the signal to the ADC 27. The ADC 27 is a processor for converting an analog pixel signal input from the CDS 26 into a digital pixel signal and outputting the signal to the line memory 28. The line memory 28 is a processor for temporarily holding the pixel signal input from the ADC 27 and outputting it to the signal processing circuit 21 for each row of the photoelectric conversion elements in the pixel array 23.

The signal processing circuit 21 is a processor for performing a predetermined signal processing relative to the pixel signal input from the line memory 28 and outputting the pixel signal to the post-stage processor 12. The signal processing circuit 21 performs the signal processing, for example, lens shading correction, defect correction, and noise reduction processing relative to the pixel signal.

In this way, the plurality of photoelectric conversion elements arranged in the pixel array 23 performs the photoelectric conversion from the incident light into the signal charge of the amount according to the amount of the received light and accumulates it, and the peripheral circuit 22 reads the signal charge accumulated in each photoelectric conversion element as the pixel signal, then, the image sensor 20 performs imaging.

Also, in the image sensor 20, an element isolation unit to electrically and optically isolate the photoelectric conversion elements from one another is embedded around a light-receiving region of each photoelectric conversion element in the pixel array 23.

In the image sensor 20, the light from the imaging optical system 13 radially enters from above the center of the pixel array 23 to the whole light-receiving surface of the pixel array 23. Therefore, the light advancing vertically downward relative to the light-receiving surface of the photoelectric conversion element is taken in the photoelectric conversion element in a central part of the pixel array 23. On the other hand, the light is obliquely taken relative to the light-receiving surface of the photoelectric conversion element in the photoelectric conversion element in a peripheral edge part of the pixel array 23.

Therefore, in the photoelectric conversion element in the peripheral edge part of the pixel array 23, a part of the oblique incident light is blocked by the element isolation unit surrounding the light-receiving region of the photoelectric conversion element and cannot. reach the light-receiving region.

As a result, in the solid state imaging device 14, since amount of the received light of the photoelectric conversion element in the peripheral edge part of the pixel array 23 is reduced as compared with that in the central part of the pixel array 23, light-reception sensitivity is reduced.

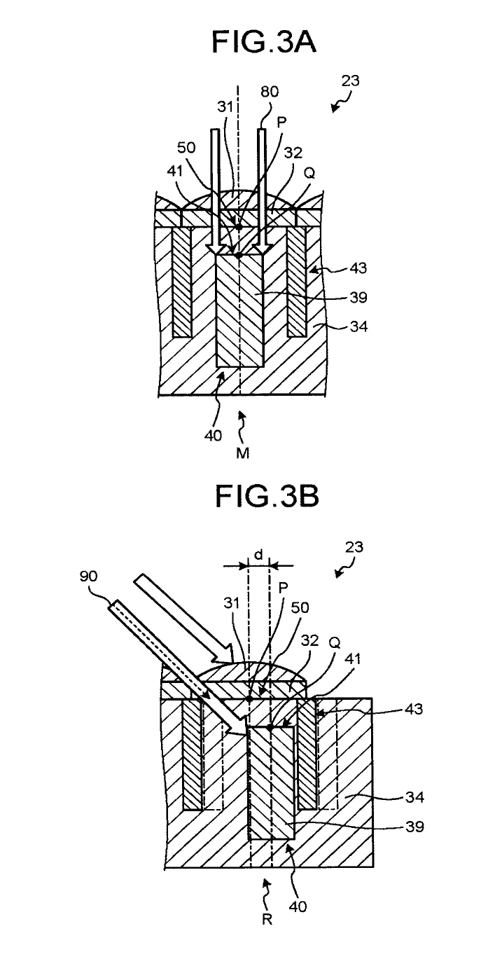

In the solid state imaging device 14 according to the present embodiment, the oblique incident light is efficiently received by the photoelectric conversion element positioned in the peripheral edge part of the pixel array 23 by adjusting an arrangement position of the element isolation unit. Accordingly, the light-reception sensitivity is improved in the solid state imaging device 14 according to the present embodiment. Next, the pixel array 23 according to the present embodiment will be described with reference to FIGS. 3A and 3B.

FIG. 3A is an explanatory diagram of a schematic cross-section surface of the central part (M) of the pixel array 23 according to the present embodiment. FIG. 3B is an explanatory diagram of a schematic cross-section surface of the peripheral edge part (R) of the pixel array 23 according to the present embodiment. Components which are necessary for the description on the pixel array 23 according to the present embodiment are illustrated in FIGS. 3A and 3B. A detailed configuration of the pixel array 23 will be described in the description on the manufacturing method for the solid state imaging device 14 including a forming method for the pixel array 23 to be described below.

The pixel array 23 includes a first conductivity type (P-type) semiconductor (here, it is assumed that Si: silicon) layer 34 as illustrated in FIGS. 3A and 3B. A second conductivity type (N-type) Si region 39 is provided at the forming position of a photoelectric conversion element 40 in the P-type Si layer 34. In the pixel array 23, a photodiode which is formed by a PN junction between the P-type Si layer 34 and the N-type Si region 39 becomes the photoelectric conversion element 40.

Also, an element isolation unit 43 having a light shielding effect is provided between the respective photoelectric conversion elements 40 adjacent to each other. The element isolation unit 43 is embedded in a depth direction from a surface of the P-type Si layer 34 around each photoelectric conversion element 40. That is, the element isolation unit 43 is embedded in the P-type Si layer 34 around each photoelectric conversion element 40 so as to define the light-receiving region in the P-type Si layer 34.

In the present embodiment, the rectangular opening region 50 is formed in a position opposed to the light-receiving region 41 on the upper end surface of each photoelectric conversion element 40 by surrounding each photoelectric conversion element 40 by the element isolation unit 43 in a rectangular shape in a plan view. Here, the upper end surface of the photoelectric conversion element 40 indicates an end surface of a side where the light enters the pixel array 23 in the photoelectric conversion element 40.

A color filter 32 is provided so as to cover the opening region 50 in the opening region 50 of each element isolation unit 43 as illustrated in FIGS. 3A and 3B. A microlens 31 is provided on an upper surface of each color filter 32 where the light enters.

Also, a center position P of the opening region 50 of the element isolation unit 43 substantially coincides with a center position Q of the light-receiving region 41 of the photoelectric conversion element 40 in the central part (M) of the pixel array 23 according to the present embodiment as illustrated in FIG. 3A. Specifically, the center position P of the opening region 50 of the element isolation unit 43 is positioned just above the center position Q of the light-receiving region 41 on the upper end surface of the photoelectric conversion element 40. Therefore, light 80 advancing vertically downward relative to the light-receiving region 41 on the upper end surface of the photoelectric conversion element 40 is taken in the central part (M) of the pixel array 23.

On the other hand, in the peripheral edge part (R) of the pixel array 23 according to the present embodiment, an arrangement position of the element isolation unit 43 is displaced to a side of the central part (M) of the pixel array 23 as illustrated in FIG. 3B. Specifically, the center position P of the opening region 50 of the element isolation unit 43 is displaced to a center side of the pixel array 23 relative to the center position Q of the light-receiving region 41 on the upper end surface of the photoelectric conversion element 40.

As illustrated in FIG. 3B, the element isolation unit 43 is placed in a position in the P-type Si layer 34 indicated by an alternate long and short dashed line before the arrangement position of the element isolation unit 43 is displaced. When the element isolation unit 43 is in this place, oblique incident light 90 (refer to as “oblique light” below) relative to the light-receiving region 41 of the photoelectric conversion element 40 is blocked.

As illustrated in FIG. 3B, the arrangement position of the element isolation unit 43 indicated by the alternate long and short dashed line is displaced to the arrangement position of the element isolation unit 43 indicated by a solid line so that the oblique light 90 which has been blocked by the element isolation unit 43 indicated by the alternate long and short dashed line reaches the photoelectric conversion element 40.

Accordingly, the opening region 50 of the element isolation unit 43 is displaced to the center side of the pixel array 23 in the peripheral edge part (R) of the pixel array 23 according to the present embodiment. As a result, the oblique light 90 which has been blocked by the element isolation unit 43 indicated by the alternate long and short dashed line reaches the photoelectric conversion element 40, and the amount of the received light of the photoelectric conversion element 40 increases.

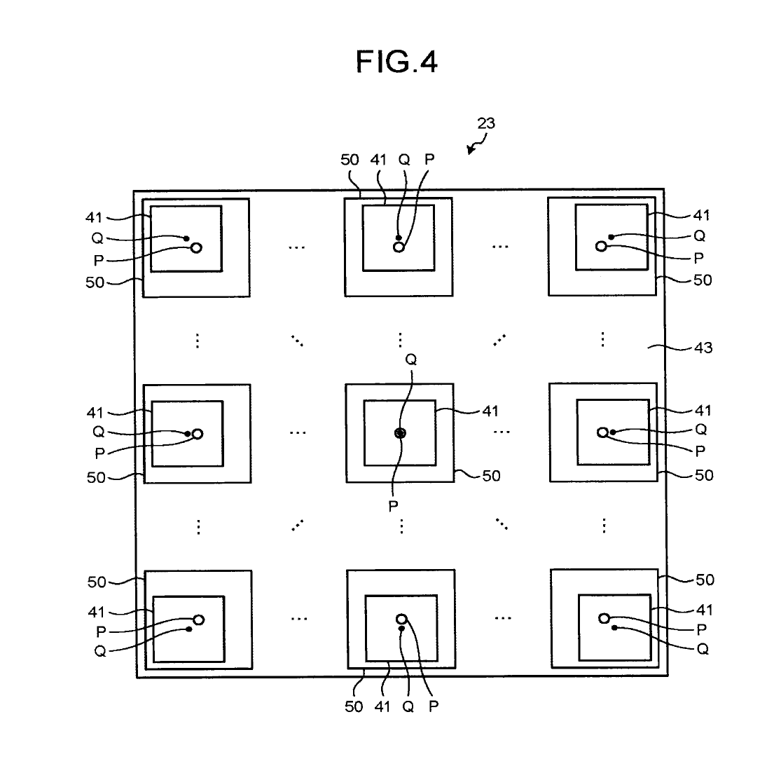

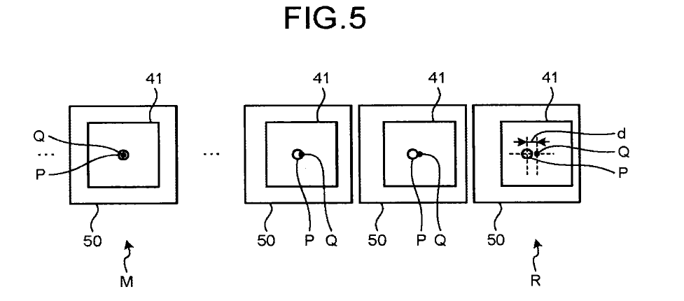

Also, in the pixel array 23 of the present embodiment, an amount of the gap d between the center position P of the opening region 50 and the center position Q of the light-receiving region 41 gets smaller step by step as the opening region 50 of the element isolation unit 43 moves from the peripheral edge part (R) of the pixel array 23 to the central part (M). This will be described with reference to FIGS. 4 and 5.

FIG. 4 is an explanatory diagram of positional relationship between the center position P of the opening region 50 of the element isolation unit 43 and the corresponding center position Q of the light-receiving region 41 of the photoelectric conversion element 40 in the pixel array 23 according to the present embodiment. Also, FIG. 5 is an explanatory diagram of a part of a situation were the amount of the gap d gets smaller step by step as it goes from the peripheral edge part of the pixel array 23 to the central part in the pixel array 23 indicated in FIG. 4.

As illustrated in FIG. 4, in the peripheral edge part of the pixel array 23, the center positions P of the opening regions 50 of the element isolation units 43 are respectively displaced to the center side of the pixel array 23 relative to the center positions Q of the light-receiving regions 41 of the photoelectric conversion elements 40. That is, the light-receiving regions 41 of the photoelectric conversion elements 40 are respectively displaced to an opposite direction to the apparent direction to which the opening regions 50 of the element isolation units 43 are displaced in the opening regions 50 of the element isolation units 43.

Also, the light from the imaging optical system 13 radially enters from above the center of the pixel array 23 to the whole light-receiving surface of the pixel array 23 in the pixel array 23. Therefore, incidence angles of the light relative to the light-receiving regions 41 on the upper end surface of the photoelectric conversion element 40 are different from one another according to a light-receiving position in the pixel array 23. Specifically, an angle formed by the light-receiving region 41 on the upper end surface of the photoelectric conversion element 40 and the light which enters the light-receiving region 41 (refer to as “incidence angle” below) gets smaller as it goes from the peripheral edge part (R) of the pixel array 23 to the central part (M).

As illustrated in FIG. 5, the amount of the gap d gets smaller in accordance with the incidence angle of the light relative to the light-receiving region 41 of each photoelectric conversion element 40 as it goes from the peripheral edge part (R) of the pixel array 23 to the central part (M).

In this way, the amount of the received light of each photoelectric conversion element 40 arranged in the pixel array 23 increases by reducing amount of the gap d in accordance with the incidence angle of the light relative to the light-receiving region 41 of each photoelectric conversion element 40 as it goes from the peripheral edge part (R) of the pixel array 23 to the central part (M).

In the pixel array 23 of the present embodiment, the arrangement position of the opening region 50 in the peripheral edge part is displaced to the center side of the pixel array 23 in consideration of the incidence angle of the light relative to the light-receiving region 41 of the photoelectric conversion element 40. Accordingly, the oblique light 90 blocked in a case where there is no gap in the element isolation unit 43 reaches the photoelectric conversion element 40, and the amount of the received light of the photoelectric conversion element 40 in the peripheral edge part increases.

Therefore, the light-reception sensitivity of the solid state imaging device 14 is improved because the amount of the received light of the photoelectric conversion element 40 in the peripheral edge part of the pixel array 23 increases and the amount of the received light of the photoelectric conversion element 40 in the central part and that in the peripheral edge part substantially become equal.

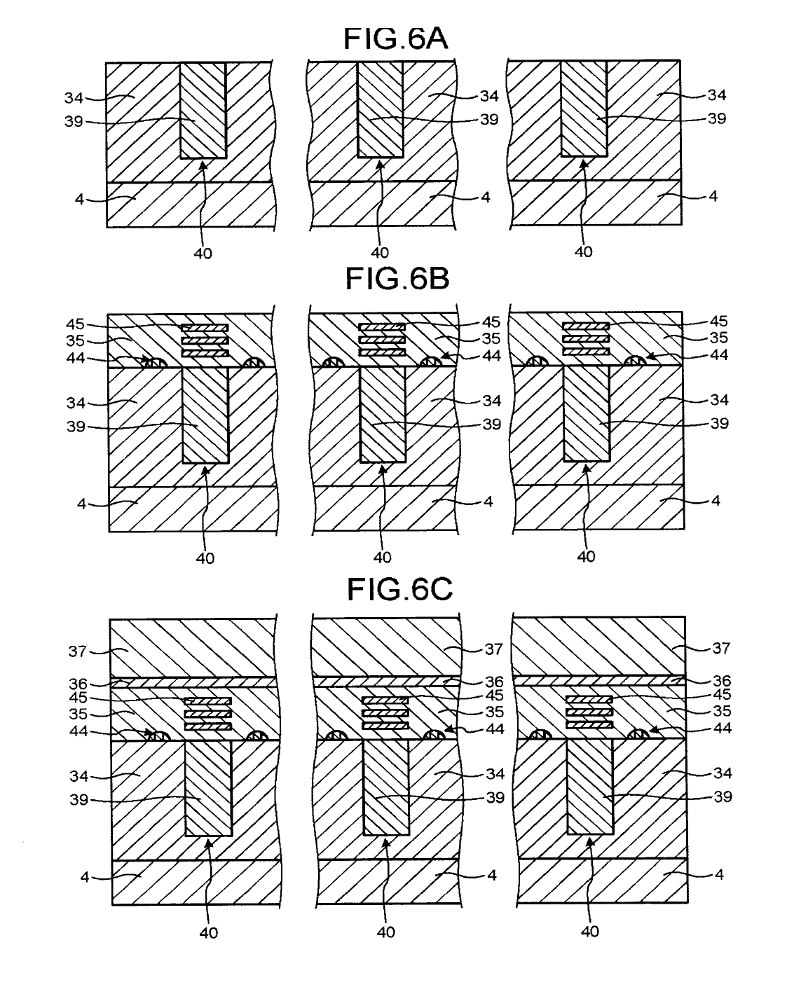

Next, a manufacturing method for the solid state imaging device 14 including the forming method for the pixel array 23 will be described with reference to FIGS. 6 to 9. The manufacturing method of parts other than the pixel array 23 in the solid state imaging device 14 is similar to that of a general CMOS image sensor. Therefore, the manufacturing method for a part of the pixel array 23 in the solid state imaging device 14 will be described below. Also, for easy understanding of the description on the present embodiment, the pixel array 23 is divided into three parts, i.e., a central part and right/left peripheral edge parts in FIGS. 6 to 9.

FIGS. 6 to 9 are cross-sectional schematic diagrams of the manufacturing process for the solid state imaging device 14 according to the embodiment. The manufacturing process of the pixel array 23 is selectively illustrated in FIGS. 6 to 9. At the same time, the components omitted in the FIGS. 3A and 3B are also illustrated in FIGS. 6 to 9.

As illustrated in FIG. 6A, the P-type Si layer 34 is formed on a semiconductor substrate 4 such as a Si wafer when the pixel array 23 is manufactured. At this time, for example, a Si layer in which a P-type impurity such as boron is doped on the semiconductor substrate 4 is epitaxially grown so as to form the P-type Si layer 34. The P-type Si layer 34 may be formed by performing the ion implantation of the P-type impurity into the Si wafer and performing annealing treatment.

Subsequently, on the forming position of the photoelectric conversion element 40 in the P-type Si layer 34, an N-type Si region 39 is two-dimensionally arranged in the P-type Si layer 34 in a matrix, for example, by performing the ion implantation of the N-type impurity such as phosphorus and performing the annealing treatment. Accordingly, the photoelectric conversion element 40 which is the photodiode is formed in the pixel array 23 by the PN junction between the P-type Si layer 34 and the N-type Si region 39.

After that, an insulation layer 35 is formed along with a read gate 44, a multilayer wiring 45, and the like on the P-type Si layer 34 as illustrated in FIG. 6B. In the process, after the read gate 44 and the like has been formed on the upper surface of the P-type Si layer 34, three processes are repeated, i.e., a process for forming a Si oxide layer, a process for forming a predetermined wiring pattern in the Si oxide layer, and a process for forming the multilayer wiring 45 by embedding Cu and the like in the wiring pattern. Accordingly, the insulation layer 35 having the read gate 44 and the multilayer wiring 45 provided therein is formed.

Subsequently, as illustrated in FIG. 6C, an adhesion layer 36 is provided on the upper surface of the insulation layer 35 by applying the adhesive thereon. A support substrate 37 such as the Si wafer is stuck on the upper surface of the adhesion layer 36. After that, the semiconductor substrate 4 is polished from a side of a reverse surface (here, a side of the upper surface), for example, by a polishing apparatus such as a grinder and thickness of the semiconductor substrate 4 is reduced until it becomes a predetermined thickness after a structure illustrated in FIG. 6C has been turned upside down.

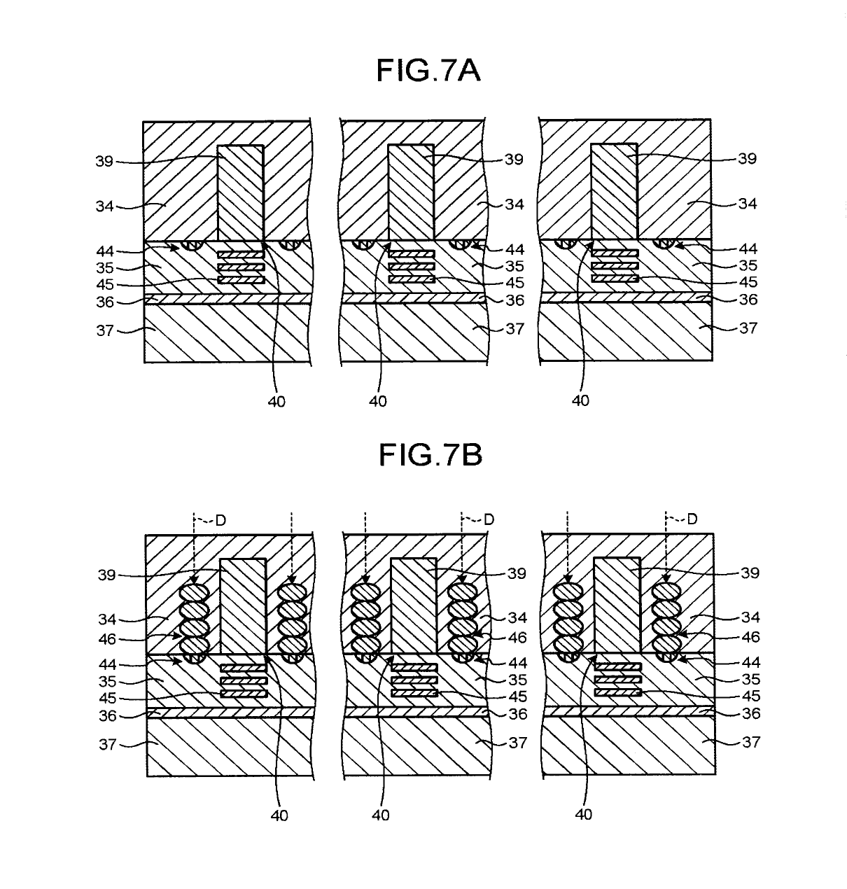

For example, the side of the reverse surface of the semiconductor substrate 4 is further polished by chemical mechanical polishing (CMP), and the reverse surface (here, the upper surface) which becomes the light-receiving surface of the P-type Si layer 34 is exposed as illustrated in FIG. 7A.

After that, as illustrated in FIG. 7B, the ion implantation of the P-type impurity D, for example, boron and boron fluoride, to the predetermined depth position is repeated a plurality of times between the respective photoelectric conversion elements 40 from the upper surface of the P-type Si layer 34 to inside the P-type Si layer 34.

At this time, the ion implantation of the P-type impurity D is sequentially repeated as ion implantation energy is weakened step by step. Accordingly, a multistage P-type doped region which has four stages in this example is formed at a predetermined depth position in the P-type Si layer 34.

After that, the P-type impurity D ion in the P-type doped region is activated by performing the annealing treatment. Accordingly, an element isolation region 46 where the P-type impurity D is doped is formed. The element isolation region 46 electrically isolates between the photoelectric conversion elements 40 adjacent to each other at a comparatively deep position of the P-type Si layer 34.

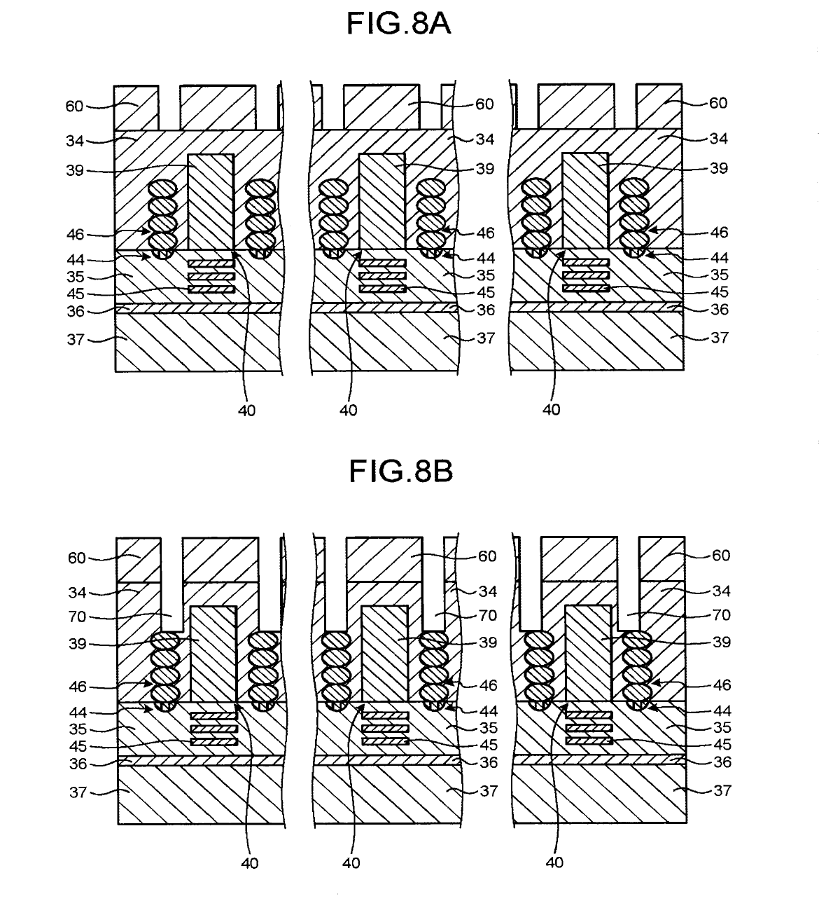

Subsequently, as illustrated in FIG. 8A, for example, a resist 60 is applied on the upper surface of the P-type Si layer 34, and then the resist 60 on a part corresponding to the forming position of the opening region 50 of the element isolation unit 43 (refer to FIG. 4) is maintained by photolithography, and the resist 60 on a part other than the above is removed.

As a specific description, a center position of the resist 60 formed in a position corresponding to the opening region 50 of the element isolation unit 43 in the peripheral edge part of the resist 60 is displaced to the center side of the pixel array 23 relative to the center position Q of the light-receiving region 41 on the upper end surface of the photoelectric conversion element 40.

Reactive ion etching (RIE) is performed by using the resist 60 as a mask. Then, as illustrated in FIG. 8B, the P-type Si layer 34 at a forming position of the element isolation unit 43 for isolating each photoelectric conversion element 40 (refer to FIGS. 3A and 3B) is removed to the upper end of the element isolation region 46, and the trench 70 is formed. At this time, the trench 70 formed in the P-type Si layer 34 in the peripheral edge part of the pixel array 23 is displaced to the center side of the pixel array 23.

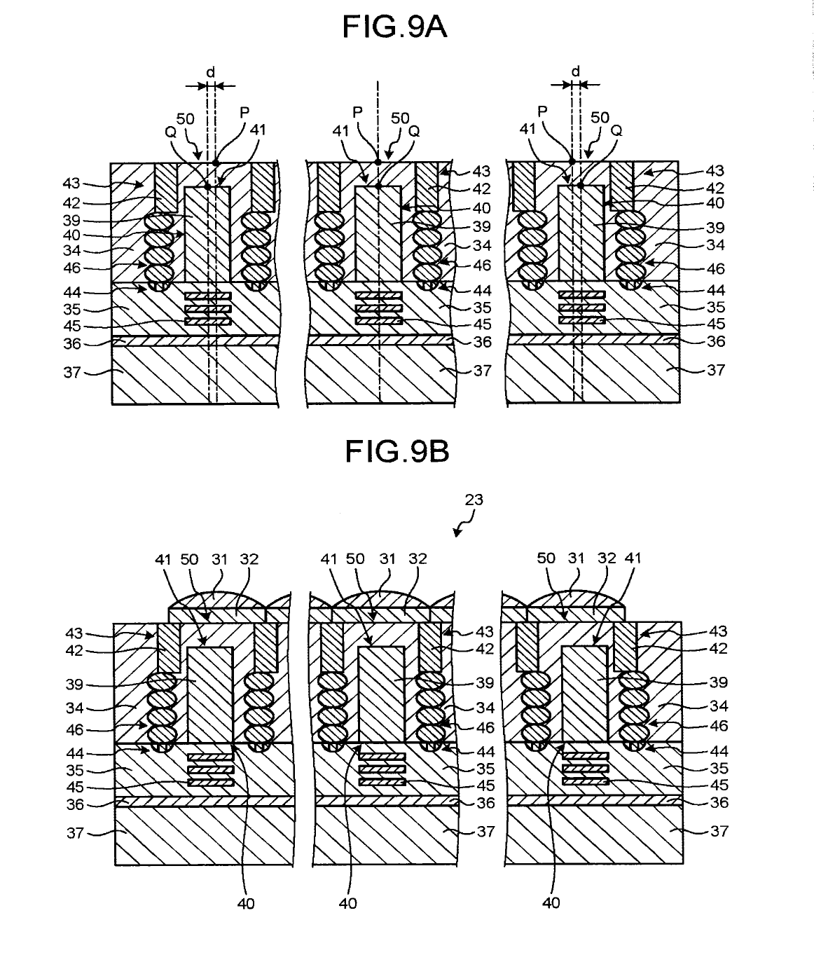

Subsequently, an insulating film configured of silicon oxide and the like is formed on an inner periphery of the trench 70 by using chemical vapor deposition (CVD), a sputter, and the like. After that, as illustrated in FIG. 9A, a light shielding member 42 such as aluminum is embedded in the trench 70 in which the inner periphery is covered by the insulating film by using the CVD, for example, and the element isolation unit 43 is formed. Accordingly, the photoelectric conversion elements 40 are electrically and optically isolated from each other.

In this way, in the peripheral edge part of the pixel array 23, the element isolation unit 43 is formed in the P-type Si layer 34. In the element isolation unit 43, the center position P of the opening region 50 of the element isolation unit 43 is displaced to the center side of the pixel array 23 relative to the corresponding center position Q of the light-receiving region 41 of the photoelectric conversion element 40.

As illustrated in FIG. 9B, the color filter 32 for selectively transmitting colored light having any one of the colors of red, green, blue, or white is formed at a position corresponding to the opening region 50 of the upper surface of the P-type Si layer 34. After that, the pixel array 23 is formed by forming the microlens 31, which concentrates the light for entering via the imaging optical system 13, on the upper surface of each color filter 32.

In the solid state imaging device 14 manufactured through the above-mentioned process, the arrangement position of the opening region 50 in the peripheral edge part in the pixel array 23 is displaced to the center side of the pixel array 23 in consideration of the incidence angle of the light relative to the light-receiving region 41 of the photoelectric conversion element 40. Accordingly, the oblique light 90 blocked in a case where there is no gap in the element isolation unit 43 reaches the photoelectric conversion element 40, and the amount of the received light of the photoelectric conversion element 40 in the peripheral edge part increases.

Therefore, the light-reception sensitivity of the solid state imaging device 14 is improved because the amount of the received light of the photoelectric conversion element 40 in the peripheral edge part of the pixel array 23 increases and the amount of the received light of the photoelectric conversion element 40 in the central part and that in the peripheral edge part substantially become equal.

Also, a so-called “scaling” is performed in the present embodiment. The scaling is to define the light-receiving region 41 of each photoelectric conversion element 40 by displacing the arrangement position of the element isolation unit 43 which is a deep trench isolation (DTI) provided in the P-type Si layer 34.

That is, the element isolation unit 43 having the light shielding effect is displaced at the position where it is embedded in the depth direction from the surface of the P-type Si layer 34 so as to surround each photoelectric conversion element 40 in the present embodiment. Therefore, for example, compared with a case where the scaling is performed by using the light shielding film provided on the P-type Si layer 34, the amount of the gap d between the center position P of the opening region 50 and the center position Q of the light-receiving region 41 corresponding to the center position P can be reduced.

Also, in the pixel array 23 manufactured through the above-mentioned process, the element isolation region 46 is formed on the side of the lower end of the element isolation unit 43 in the P-type Si layer 34. The element isolation unit 43 and the element isolation region 46 prevent the flow of the electrons from the adjacent photoelectric conversion element 40 in the present embodiment. Here, the lower end of the element isolation unit 43 indicates an opposite end to the side where the light enters the pixel array 23 in the element isolation unit 43.

In the present embodiment, the element isolation unit 43 is formed after the element isolation region 46 has been formed in the P-type Si layer 34. Therefore, the element isolation unit 43 is formed from the upper surface of the P-type Si layer 34 to the upper end of the element isolation region 46. That is, the element isolation region 46 for electrically isolating the elements is formed in the deep part of the P-type Si layer 34, and the element isolation unit 43 for electrically and optically isolating the elements is formed in a surface part of the P-type Si layer 34.

It is necessary for the element isolation unit 43 formed in the surface part of the P-type Si layer 34 to have optical characteristics to define each photoelectric conversion element 40. On the other hand, it is not necessary for the element isolation region 46 formed in the deep part of the P-type Si layer 34 to have the optical characteristics. That is, the element isolation region 46 of the present embodiment is formed in order to prevent the flow of the electrons from the adjacent photoelectric conversion element 40.

In this way, since the depth of the trench 70 formed in the P-type Si layer 34 can be reduced by forming the element isolation region 46 at the predetermined depth position in the P-type Si layer 34, a negative effect on the P-type Si layer 34 by the RIP can be reduced.

In the above-mentioned embodiment, the element isolation unit 43 is formed after the element isolation region 46 has been formed in the P-type Si layer 34. However, the element isolation region 46 may be formed in the P-type Si layer 34 below the position of the trench 70 after the trench 70 has been formed in the P-type Si layer 34.

In this case, the ion implantation of the P-type impurity D is performed from a bottom surface of the trench 70 to the depth direction of the P-type Si layer 34. Therefore, the P-type doped region can be formed with the weaker ion implantation energy than that of the above-mentioned embodiment.

Also, a case has been described above where the image sensor 20 according to the embodiment is the rear surface irradiation type image sensor. However, configurations of the above-mentioned element isolation unit 43 and the element isolation region 46 can be applied to the surface irradiation type image sensor.

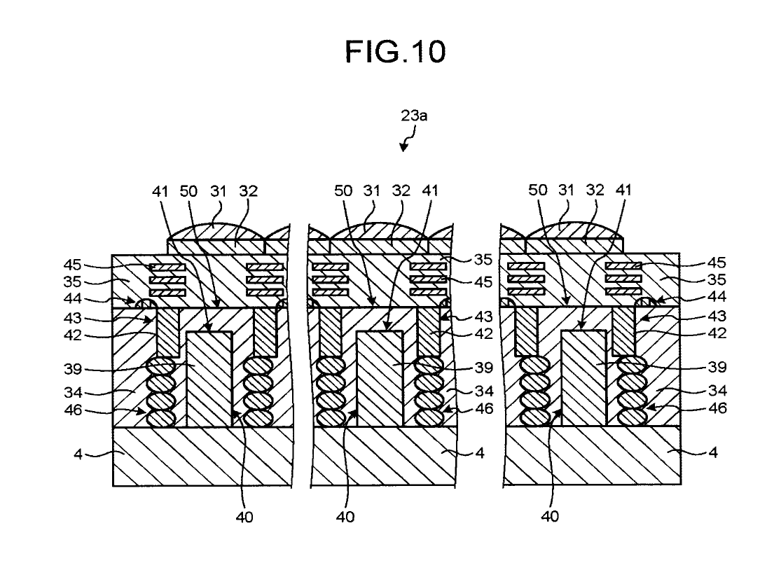

FIG. 10 is an explanatory diagram in a case where the configurations of the element isolation unit 43 and the element isolation region 46 according to the embodiment are applied to the surface irradiation type image sensor. A part of a schematic cross-section surface of a pixel array 23a in the surface irradiation type image sensor is illustrated in FIG. 10. Among components indicated in FIG. 10, the description is omitted by denoting with the same symbols as those in FIG. 9B regarding the components having the similar functions to those indicated in FIG. 9B.

As illustrated in FIG. 10, the pixel array 23a has the similar configuration to that of the pixel array 23 in FIG. 9B except for a point that the P-type Si layer 34 is provided on the semiconductor substrate 4 and a point that the insulation layer 35 having the read gate 44 and the multilayer wiring 45 provided therein is arranged on the side of the light-receiving surface (upper surface) of the P-type Si layer 34.

Therefore, in the pixel array 23a illustrated in FIG. 10, an arrangement position of the element isolation unit 43 is displaced to the center side of the pixel array 23a in a peripheral edge part of the pixel array 23a.

With this configuration, the light-reception sensitivity is improved because the amount of the received light of the photoelectric conversion element 40 in the peripheral edge part of the pixel array 23a increases and the amount of the received light of the photoelectric conversion element 40 in the central part and that in the peripheral edge part substantially become equal.

In the above-mentioned embodiment, it has been assumed that the Si layer 34 and the element isolation region 46 be P-type and the Si region 39 be N-type. However, the pixel array 23 may be configured while assuming that the Si layer 34 and the element isolation region 46 be N-type and the Si region 39 be P-type.

Also, in the above-mentioned embodiment, the amount of the gap d gets smaller step by step as it goes from the peripheral edge part (R) of the pixel array 23 to the central part (M). However, the arrangement position of the opening region 50 of the element isolation unit 43 is not limited to this configuration.

For example, the pixel array 23 is divided into blocks including the plurality of opening regions 50, and the amount of the gap d for each block may get smaller step by step as it goes from the peripheral edge part (R) of the pixel array 23 to the central part (M).

With this configuration, similarly to the above-mentioned configuration, the oblique light 90 efficiently reaches the light-receiving region 41 of the photoelectric conversion element 40. The amount of the received light of the photoelectric conversion element 40 in the central part and that in the peripheral edge part substantially become equal, and the light-reception sensitivity of the solid state imaging device 14 is improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid state imaging device comprising:
an imaging area where a plurality of photoelectric conversion elements is two-dimensionally arranged in a matrix in a semiconductor layer; and
an element isolation unit for being embedded so as to surround a light-receiving region of each photoelectric conversion element and having a light shielding effect, wherein
a center position of an opening region surrounding the light-receiving region is positioned on a center side of the imaging area than a corresponding center position of the light-receiving region.

2. The solid state imaging device according to claim 1, comprising:
an element isolation region for extending from a lower end of the element isolation unit in the semiconductor layer in a depth direction and including a same conductivity type impurity as an impurity included in the semiconductor layer.

3. The solid state imaging device according to claim 1, wherein
the opening region has a smaller amount of a gap between the center position of the opening region and the center position of the light-receiving region as an arrangement position is closer to the center position of the imaging area.

4. The solid state imaging device according to claim 3, wherein
the opening regions are adjacent to each other at regular intervals.

5. The solid state imaging device according to claim 1, wherein
the element isolation unit surrounds the light-receiving region of each photoelectric conversion element in a rectangular shape in a plan view.

6. The solid state imaging device according to claim 1, wherein
the element isolation unit is formed by embedding a light shielding member in a groove formed by an etching to the semiconductor layer.

7. The solid state imaging device according to claim 2, wherein
the element isolation region is formed by ion implantation of the impurity to the semiconductor layer.

8. A manufacturing method for a solid state imaging device comprising:
forming an imaging area where a plurality of photoelectric conversion elements is two-dimensionally arranged by forming the photoelectric conversion elements are formed in a matrix in a semiconductor layer;
forming a groove, in which a center position of a region around the light-receiving region is displaced to a center side in the imaging area relative to a center of the light-receiving region, for surrounding a light-receiving region of the photoelectric conversion element is formed in the semiconductor layer; and
forming an element isolation unit for isolating the photoelectric conversion elements from each other by embedding a light shielding member in the groove.

9. The manufacturing method for a solid state imaging device according to claim 8, further comprising:
forming an element isolation region for isolating the photoelectric conversion elements from each other by diffusing a same conductivity type impurity as an impurity included in the semiconductor layer from a lower end of a forming region of the groove in a depth direction.

10. The manufacturing method for a solid state imaging device according to claim 8, comprising:
reducing an amount of a gap between a center position of a region surrounded by the groove and a center position of the light-receiving region surrounded by the groove as a forming position of the groove is closer to a center position of the imaging area when the groove is formed.

11. The manufacturing method for a solid state imaging device according to claim 8, comprising:
maintaining regular intervals of the grooves adjacent to each other when the groove is formed.

12. The manufacturing method for a solid state imaging device according to claim 8, comprising:
forming the groove so as to surround the light-receiving region of the photoelectric conversion element in a rectangular shape in a plan view.

13. The manufacturing method for a solid state imaging device according to claim 8, comprising:
forming an insulating film on an inner periphery of the groove; and
embedding a metal in the groove on which the insulating film is formed when the element isolation unit is formed.

14. The manufacturing method for a solid state imaging device according to claim 9, comprising:
performing ion implantation and thermal diffusion of the impurity to the semiconductor layer when the element isolation region is formed.

15. The manufacturing method for a solid state imaging device according to claim 8, comprising:
defining the light-receiving region of the photoelectric conversion element according to a forming position of the element isolation unit.
